(19) United States
(12) Patent Application Publication
(10) Pub. No.: US 2016/0372523 A1
(43) Pub. Date: Dec. 22, 2016

(54) DISPLAY DEVICE

(71) Applicant: Japan Display Inc., Tokyo (JP)

(72) Inventors: Ryoichi ITO, Tokyo (JP); Toshihiro SATO, Tokyo (JP)

(21) Appl. No.: 15/186,586

(22) Filed: Jun. 20, 2016

(30) Foreign Application Priority Data
Jun. 19, 2015 (JP) 2015-124169

(51) Int. Cl. H01L 27/32; H01L 51/52

(52) U.S. Cl. CPC H01L 27/323; H01L 27/322; H01L 51/5234; H01L 51/5218

(57) ABSTRACT

A display device includes: a light emitting element layer which emits light, with luminance controlled in each of a plurality of unit pixels forming an image; a color filter layer which has colored layers of a plurality of colors, with the colored layer of one color corresponding to one of the unit pixels; a counter substrate; and an electrode of a first electrode pattern and an electrode of a second electrode pattern provided on both sides of the counter substrate, respectively, in order to detect a touch input. The colored layers next to each other are districted by a partition wall. At least a part of the partition wall in a direction of height is formed by the first electrode pattern.

### CROSS-REFERENCE TO RELATED APPLICATION

The present application claims priority from Japanese application JP2015-124169 filed on Jun. 19, 2015, the content of which is hereby incorporated by reference into this application.

### BACKGROUND OF THE INVENTION

1. Field of the Invention

The present invention relates to a display device.

2. Description of the Related Art

Conventionally, as an organic EL (electro-luminescence) display device, a configuration is known in which a plurality of colored layers forming a color filter layer is divided corresponding to each unit pixel and thus formed on a sealing layer covering an organic EL element (see JP2014-089804A, for example).

In the case where the colored layers are formed next to each other, there is a risk of mixture of colors of light between the unit pixels.

### SUMMARY OF THE INVENTION

In view of the foregoing problem, it is an object of the invention to provide a display device in which the mixture of colors of light between unit pixels is retrained.

According to an aspect of the invention, a display device includes: a light emitting element layer which emits light, with luminance controlled in each of a plurality of unit pixels forming an image; a color filter layer which has colored layers of a plurality of colors, with the colored layer of one color corresponding to one of the unit pixels; an insulating layer including at least one layer; and a first electrode and a second electrode provided on both sides of the insulating layer, respectively, in order to detect a touch input. The colored layers next to each other are districted by a partition wall. At least a part of the partition wall in a direction of height is formed by the first electrode.

### BRIEF DESCRIPTION OF THE DRAWINGS

FIG. 1 is a schematic cross-sectional view showing the configuration of a display device according to a first embodiment.

FIG. 2 is a perspective view showing an outline of the display device according to the first embodiment.

FIG. 3A is an enlarged view around an area A in FIG. 2, showing an example of the arrangement of a first electrode pattern.

FIG. 3B is an enlarged view around the area A in FIG. 2, showing an example of the arrangement of the first electrode pattern.

FIG. 3C is an enlarged view around the area A in FIG. 2, showing an example of the arrangement of the first electrode pattern.

FIG. 3D is an enlarged view around the area A in FIG. 2, showing an example of the arrangement of the first electrode pattern.

FIG. 4 is a perspective view showing a second electrode pattern in addition to the configuration shown in FIG. 2.

FIG. 5A is an enlarged view around an area A in FIG. 4, showing an example of the arrangement of the first electrode pattern and the second electrode pattern.

FIG. 5B is an enlarged view around the area A in FIG. 4, showing an example of the arrangement of the first electrode pattern and the second electrode pattern.

FIG. 6 is a schematic cross-sectional view showing a display device according to a modification of the first embodiment.

FIG. 7 is a schematic cross-sectional view showing a display device according to a second embodiment.

FIG. 8 is a perspective view showing an outline of the display device according to the second embodiment.

FIG. 9A is an enlarged view around an area B in FIG. 8, showing an example of the arrangement of a second electrode pattern.

FIG. 9B is an enlarged view around the area B in FIG. 8, showing an example of the arrangement of the second electrode pattern.

FIG. 9C is an enlarged view around the area B in FIG. 8, showing an example of the arrangement of the second electrode pattern.

FIG. 9D is an enlarged view around the area B in FIG. 8, showing an example of the arrangement of the second electrode pattern.

FIG. 10 is a schematic cross-sectional view showing a display device according to a modification of the second embodiment.

FIG. 11 is a schematic cross-sectional view showing a display device according to a third embodiment.

FIG. 12 is a schematic cross-sectional view showing a display device according to a fourth embodiment.

FIG. 13 is a schematic cross-sectional view showing a display device according to a fifth embodiment.

### DETAILED DESCRIPTION OF THE INVENTION

Hereinafter, embodiments of the invention will be described with reference to the drawings.

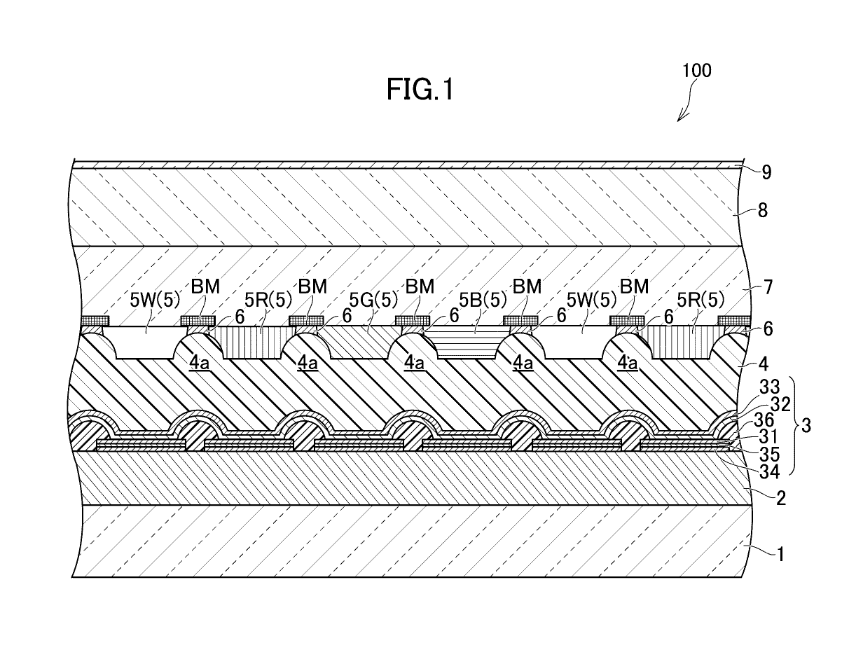

First, an organic EL (electro-luminescence) display device (hereinafter referred to simply as a display device) 100 according to a first embodiment will be described with reference to FIG. 1 to FIG. 6. The display device 100 is a touch input-type display device which has a first electrode pattern 6 and a second electrode pattern 9 and which detects a change in the electrostatic capacitance between an electrode 6a (first electrode) of the first electrode pattern 6 and an electrode 9a (second electrode) of the second electrode pattern 9 due to a press on a display on a screen by a user, and thus enables an operation of an apparatus.

FIG. 1 is a schematic cross-sectional view showing the configuration of the display device 100 according to the first embodiment. The display device 100 has a circuit layer-side substrate 1, a circuit layer 2, a light emitting element layer 3, an underlying layer 4, a color filter layer 5, the first electrode pattern 6, a filling layer 7, a counter substrate 8, and the second electrode pattern 9. These are stacked on each other, forming a multilayer structure.

The circuit layer-side substrate 1 is made of transparent glass. The circuit layer 2 is formed on the circuit layer-side substrate 1. Although its detailed configuration is not shown in FIG. 1, the circuit layer 2 is a substrate on which multiple thin film transistors for controlling the light emission of the light emitting element layer 3 are arranged in the form of a matrix.

The light emitting element layer 3 has a lower electrode 31, an organic EL layer 32 which emits light, an upper electrode 33, an ITO (indium tin oxide) layer 34, a reflection layer 35, and a bank layer 36. The light emitting element layer 3 emits light, with luminance controlled in each of a plurality of unit pixels (subpixels) forming an image. The ITO layer 34 is a transparent conductive layer formed on the circuit layer 2. The reflection layer 35 is a layer formed on the ITO layer 34 and made of a metal such as silver.

In the first embodiment, one pixel is formed by a plurality of subpixels. A plurality of subpixels developing different colors collectively forms one pixel and thus enables color display on the display device 100.

Although simplified in the illustration of FIG. 1, the organic EL layer 32 includes an electron carrying layer, a light emitting layer and a hole carrying layer stacked in order from the cathode side toward the anode side. The lower electrode 31 functions as the anode and is made of ITO. The upper electrode 33 functions as the cathode and is made of IZO (indium zinc oxide).

When a DC voltage is applied to the lower electrode 31 and the upper electrode 33, holes injected from the side of the lower electrode 31 travel through the hole carrying layer, and electrons injected from the side of the upper electrode 33 travel through the electron carrying layer. The holes and electrons then reach the organic EL layer 32 and recombine with each other. By such a recombination of electrons and holes, the light emitting element layer 3 emits light with a predetermined wavelength. The lower electrode 31 is formed in such a way as to cover a part to be a light emitting area. The bank layer 36 is formed at a part to be a non-light emitting area. The organic EL layer 32 is formed in such a way as to cover the lower electrode 31. However, in the non-light emitting area, the organic EL layer 32 is separated from the lower electrode 31 by the bank layer 36.

The organic EL layer 32 and the upper electrode 33 are in a shape following the shape of the bank layer 36, in the part to be the non-light emitting area. The underlying layer 4 is formed in such a way as to cover the upper electrode 33. The surface of the underlying layer 4 opposite to its surface facing the upper electrode 33 is convex, following the shape of the upper electrode 33 (bank layer 36).

In the first embodiment, the electrode 6a of the first electrode pattern 6, which is one of the electrodes for detecting a touch input, is formed on each of convex parts 4a of the underlying layer 4.

The color filter layer 5 has colored layers of a plurality of colors and is formed on the underlying layer 4 in such a way that a colored layer of one color corresponds to one of the unit pixels. In the first embodiment, the color filter layer 5 has a white colored layer 5W, a red colored layer 5R, a green colored layer 5G and a blue colored layer 5B.

The colored layers 5W, 5R, 5G, 5B are formed between the respective convex parts 4a of the underlying layer 4. The colored layers next to each other are districted by partition walls. In the first embodiment, the convex parts 4a of the underlying layer 4 form lower parts of the partition walls, and the first electrode pattern 6 forms upper parts of the partition walls. As shown in FIG. 1, the height of the partition walls is substantially the same as the height of the colored layers, and the colored layers next to each other are separated from each other by the partition walls.

The colored layers 5W, 5R, 5G, 5B are formed by an inkjet printing method. In the first embodiment, since the areas filled with the materials of the colored layers of the respective colors are districted by the partitions walls, there is no mixture of the materials of the respective colored layers at the time of filling the colored layers.

Also, a black matrix BM which functions as a light shielding film is formed on the first electrode pattern 6. Therefore, light is intercepted between the colored layers (subpixels) next to each other and optical mixture of colors is restrained. As shown in FIG. 1, the black matrix BM is formed in such a way as to bridge the colored layers next to each other.

Moreover, the filling layer 7 is formed in such a way as to cover the color filter layer 5 and the first electrode pattern 6, and the counter substrate 8 is stacked on the filling layer 7. The filling layer 7 and the counter substrate 8 are made of a transparent insulating material. The filling layer 7 and the counter substrate 8 in the first embodiment are a configuration corresponding to the insulating layer of the invention. The filling layer 7 corresponding to a first layer of the insulating layer, and the counter substrate 8 corresponds to a second layer of the insulating layer.

The second electrode pattern 9 is formed on the counter substrate 8. When the user touches the screen, the touch input is detected by the electrode 9a of the second electrode pattern 9 and the electrode 6a of the first electrode pattern 6, and an operation of the apparatus is carried out. In the first embodiment, the electrode 9a is made of a transparent conductive material. In the invention, the electrode 6a need not be formed of a transparent conductive material and may be a metal wire. The black matrix BM is formed on the first electrode pattern 6 and prevents reflection of external light by the metal wire. The transparent conductive material may be ITO, for example.

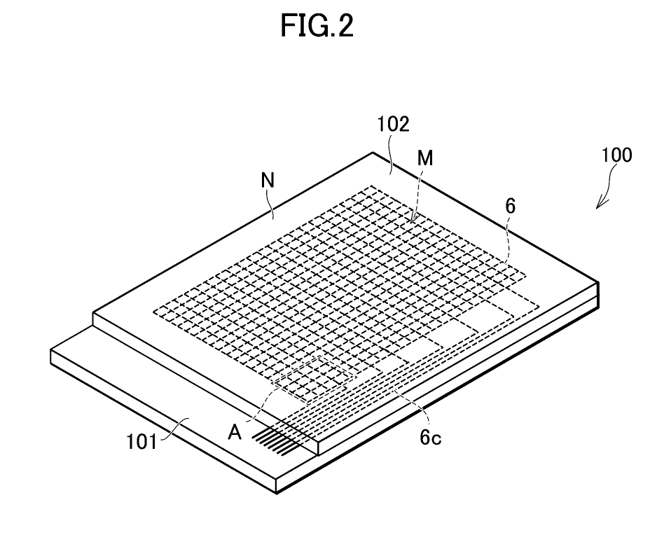

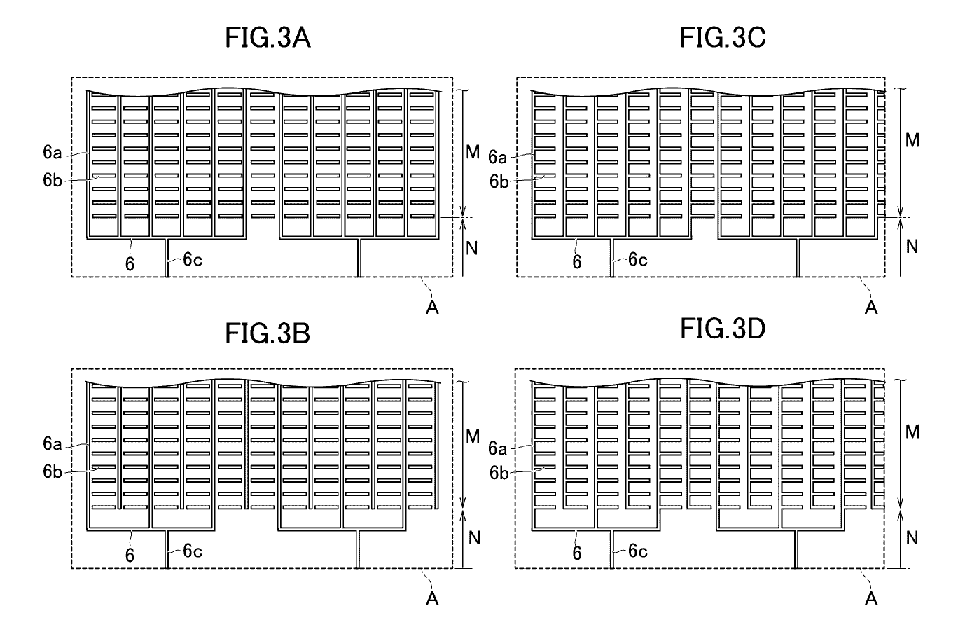

Now, the configuration of the first electrode pattern 6 will be described with reference to FIG. 2 and FIGS. 3A to 3D. FIG. 2 is a perspective view showing an outline of the display device according to the first embodiment. FIGS. 3A to 3D are enlarged views around an area A in FIG. 2, showing various arrangements of the first electrode pattern.

The multilayer structure of the display device 100 is as described with reference to FIG. 1. In FIG. 2, as a matter of convenience for the explanation, only a substrate 101 including the circuit layer-side substrate 1, the circuit layer 2, the light emitting element layer 3 and the underlying layer 4, a substrate 102 including the filling layer 7 and the counter substrate 8, and the first electrode pattern 6, are shown, and the second electrode pattern 9 or the like is omitted. The first electrode pattern 6 is formed between the substrate 101 and the substrate 102.

The display device 100 has a display area M including a plurality of subpixels provided in the form of a matrix, and a peripheral area N around the display area M. The first electrode is formed in the area corresponding to the display area M.

As shown in FIG. 2, a wire 6c electrically connected to the electrode 6a is provided in the peripheral area N. A plurality of the wires 6c are provided, and their ends are connected to terminals. A flexible wiring board is connected to the terminal to which the wires 6c are connected.

Here, details of the arrangement of the electrode 6a will be described. First, an arrangement pattern of the electrode 6a will be described with reference to FIG. 3A. As shown in FIG. 3A, the first electrode pattern 6 has a plurality of thin line-like electrodes 6a extending in one direction and provided at a substantially equal interval. The electrodes 6a are electrically connected to the wires 6c provided in the peripheral area N around the display area M In the areas between the plurality of electrodes 6a, short line-like electrodes 6b extending in a direction orthogonal to the electrodes 6a are arranged at a substantially equal interval. As the electrodes 6b are provided, the blank areas between the electrodes 6a are filled and the electrodes 6a are restrained from being viewed as stripes even when the user looks at the display area M obliquely.

It is preferable that the space between the plurality of electrodes 6a and the space between the plurality of electrodes 6b are such that a pair of electrodes 6a next to each other and a pair of electrodes 6b next to each other surround one subpixel. In other words, an area surrounded by four electrodes made up of a pair of electrodes 6a next to each other and a pair of electrodes 6b next to each other is the area corresponding to one subpixel.

The arrangement of the first electrode pattern 6 shown in FIG. 3A is only an example and this arrangement is not limiting. For example, the first electrode pattern 6 may also be arranged as shown in FIGS. 3B to 3D.

That is, the electrodes 6a connected to the wires 6c may be thinned out, as shown in FIG. 3B. If the number of the electrodes 6a connected to the wires 6c is adjusted in this manner, the electrostatic capacitance between the electrodes 6a of the first electrode pattern 6 and the electrodes 9a of the second electrode pattern 9 can be adjusted and therefore the sensitivity to a touch input can be adjusted.

Also, the electrodes 6b may be connected at one ends to the electrode 6a, as shown in FIG. 3C. In the configuration of FIG. 3A, the electrodes 6a and the electrodes 6b surrounding one subpixels are separated from each other at four positions, whereas in the configuration of FIG. 3C, the electrodes 6a and the electrodes 6b surrounding one subpixels are separated from each other at two positions. Therefore, the light shielding property and reflectivity between subpixels are improved. Thus, the optical mixture of colors between subpixels is restrained.

Also, the electrodes 6a connected to the wires 6c in the configuration of FIG. 3C may be thinned out, as shown in FIG. 3D. If such a configuration is employed, the optical mixture of colors between subpixels can be restrained while the sensitivity to a touch input can be adjusted, as described above.

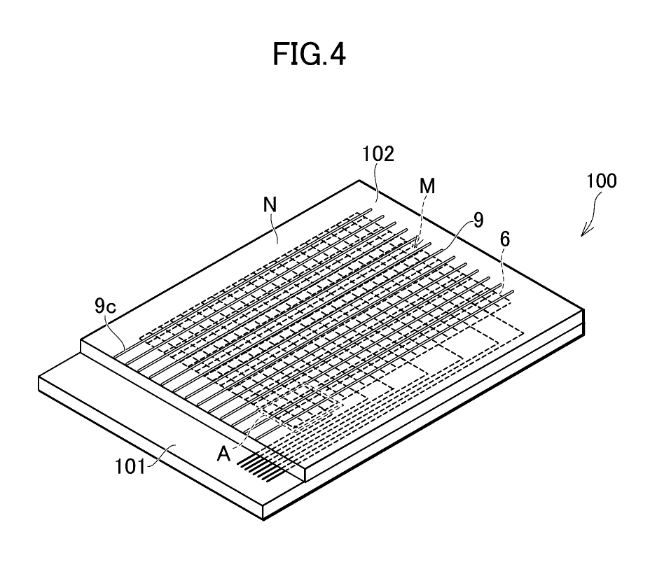

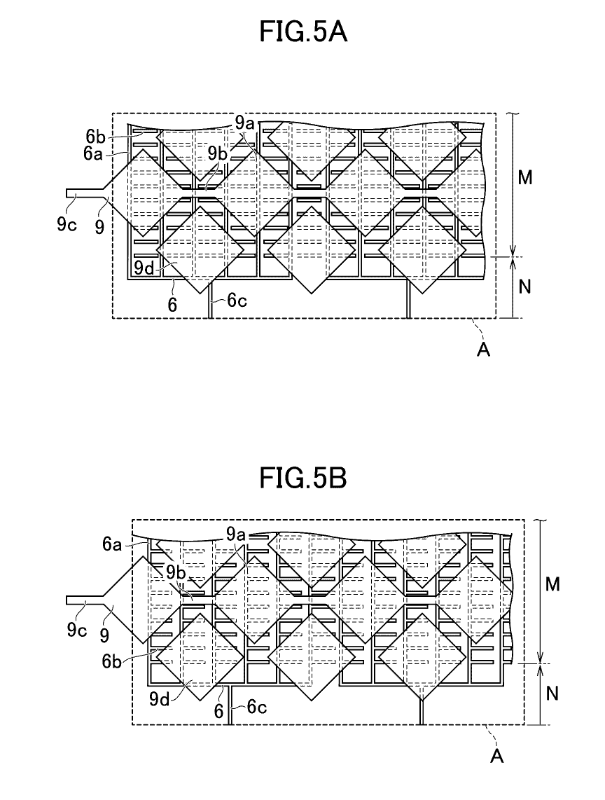

Moreover, the configuration of the second electrode pattern 9 will be described with reference to FIG. 4 and FIGS. 5A and 5B. FIG. 4 is a perspective view showing the second electrode pattern 9 in addition to the configuration shown in FIG. 2. FIGS. 5A and 5B are enlarged views of an area A in FIG. 4, showing various arrangements of the first electrode pattern 6 and the second electrode pattern 9. The second electrode pattern 9 is formed on the substrate 102.

FIG. 5A shows the state where the second electrode pattern 9 is arranged on the first electrode pattern 6 shown in FIG. 3A. FIG. 5B shows the state where the second electrode pattern 9 is arranged on the first electrode pattern 6 shown in FIG. 3C.

The electrodes 9a are electrically connected to a wire 9c provided in the peripheral area N. A plurality of the wires 9c are provided, and their ends are connected to terminals. A flexible wiring board is connected to the terminal to which the wires 9c are connected. Also, the second electrode pattern 9 has thin line-like electrodes 9b extending in a direction orthogonal to the direction in which the electrodes 6a of the first electrode pattern 6 extend, and the electrodes 9a having a size that covers a plurality of subpixels and having a substantially rhombic planar shape.

Here, if the blank areas between the electrodes 9a are large, any unevenness in the display is visually recognized when the user looks at the display area M obliquely. Therefore, in the first embodiment, dummy patterns 9d that are made of the same material as the electrodes 9a but not electrically connected to the terminal are provided. As the dummy patterns 9d are provided, the blank areas between the electrodes 9a are filled and any unevenness in the display is less visible even when the user looks at the display area M obliquely.

As described above, in the first embodiment, since the colored layers 5W, 5R, 5G, 5B are districted by the first electrode pattern 6 and the convex parts 4a of the underlying layer 4 functioning as the partition walls, the optical mixture of colors is restrained. Consequently, contrast and visibility are improved. Also, since the partition walls are formed to substantially the same height as the areas filled with the materials of the colored layers, the materials of the colored layers next to each other do not mix with each other at the time of filling the colored layers, and the respective colored layers are separated from each other by the partition walls, thus restraining the optical mixture of colors. Also, since the first electrode pattern 6 for detecting a touch input also plays the role of partition walls, there is no need to provide any separate member to form the partition walls, and a reduction in the thickness of the device and a reduction in cost can be achieved.

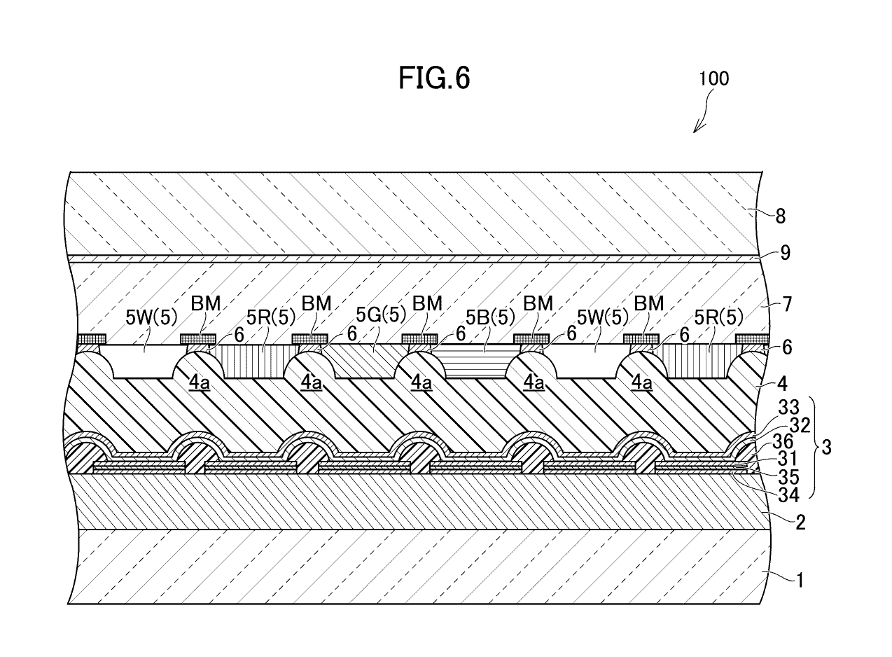

FIG. 6 is a schematic cross-sectional view showing a display device according to a modification of the first embodiment. While the configuration in which the second electrode pattern 9 is formed on the top surface of the counter substrate 8 is described with reference to FIG. 1, the second electrode pattern 9 may be formed on the bottom surface of the counter substrate 8, as shown in FIG. 6. Even with such a configuration where the first electrode pattern 6 and the second electrode pattern 9 for detecting a touch input are provided respectively on both sides of the filling layer 7 as an insulating layer, effects similar to those described in the first embodiment can be achieved.

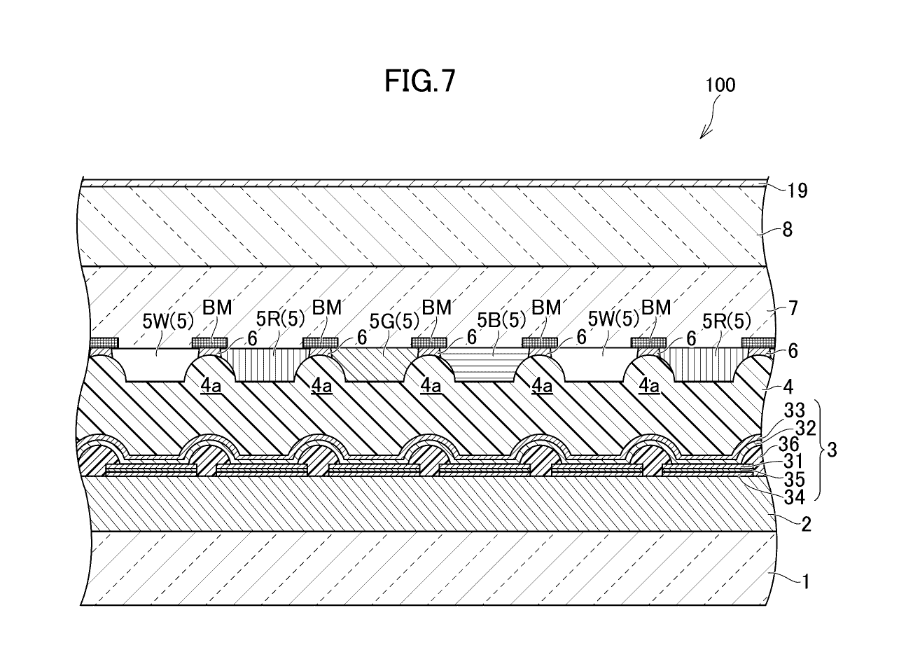

Next, a display device according to a second embodiment will be described with reference to FIGS. 7 to 9D.

FIG. 7 is a schematic cross-sectional view showing the display device according to the second embodiment. In the first embodiment, a transparent conductive material is used as the material of the second electrode pattern, whereas in the second embodiment, a low-reflection metal is used as the material of the second electrode pattern. The first electrode pattern 6 in the second embodiment is similar to that described in the first embodiment. The same configurations as those in the first embodiment are denoted by the same reference signs and will not be described further in detail.

As shown in FIG. 7, the display device 100 according to the second embodiment has a second electrode pattern 19 as a low-reflection metal film on the counter substrate 8. As the low-reflection metal, titanium, tungsten, molybdenum and the like, which are metals having a lower reflectivity for visible range than aluminum, may be used. The low-reflection metal reflects a part of incident light and absorbs the rest of the light.

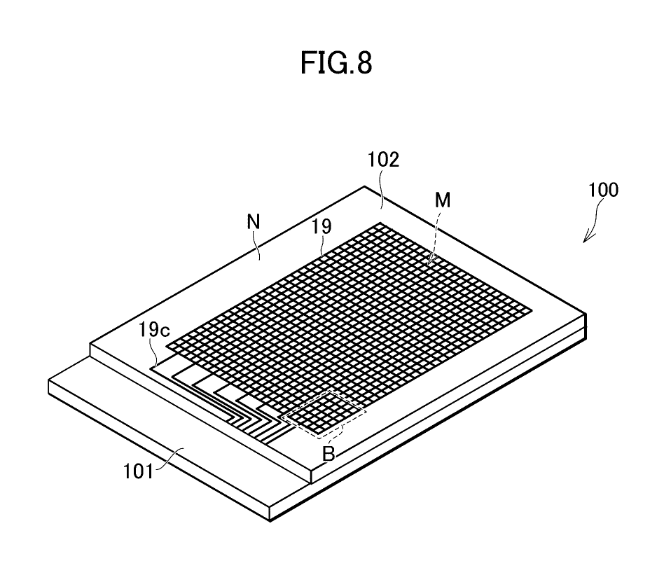

FIG. 8 is a perspective view showing an outline of the display device according to the second embodiment. As shown in FIG. 8, a wire 19c electrically connected to electrodes 19a (second electrodes) is provided in the peripheral area N. A plurality of the wires 19c are provided, and their ends are connected to terminals, not shown.

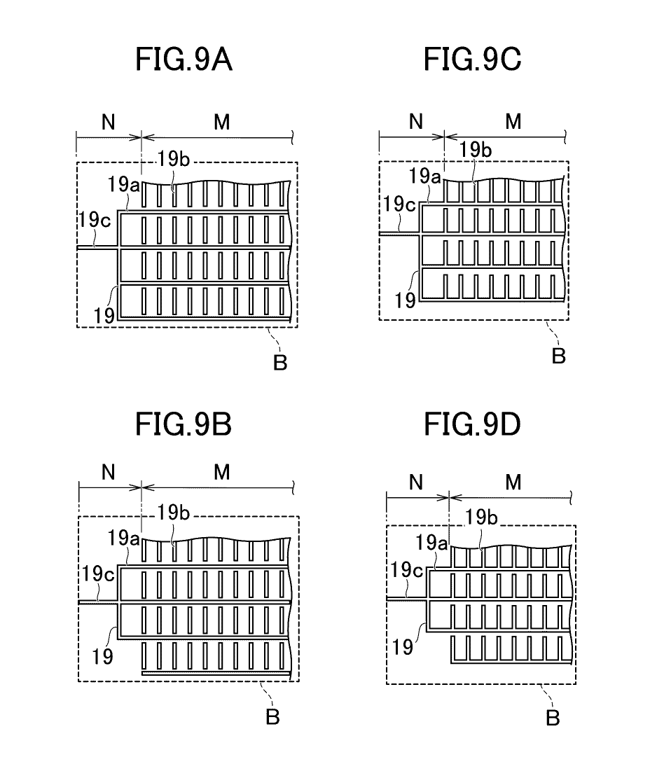

FIGS. 9A to 9D are enlarged views around an area B in FIG. 8, showing various arrangements of the second electrode pattern. Here, details of the arrangements of the second electrode pattern 19 in the second embodiment will be described. First, an arrangement pattern of the second electrode pattern 19 will be described with reference to FIG. 9A. As shown in FIG. 9A, the second electrode pattern 19 has a plurality of thin line-like electrodes 19a extending in one direction and provided at a substantially equal interval. The electrodes 19a are electrically connected to the wires 19c provided in the peripheral area N around the display area M.

In the areas between the electrodes 19a thus arranged, short line-like electrodes 19b extending in a direction orthogonal to the electrodes 19a are arranged at a substantially equal interval. It is preferable that the space between the plurality of electrodes 19a and the space between the plurality of electrodes 19b are such that a pair of electrodes 19a next to each other and a pair of electrodes 19b next to each other surround a subpixel. In other words, an area surrounded by four electrodes made up of a pair of electrodes 19a next to each other and a pair of electrodes 19b next to each other is the area corresponding to one subpixel.

The arrangement of the second electrode pattern 19 shown in FIG. 9A is only an example and this arrangement is not limiting. For example, the second electrode pattern 19 may also be arranged as shown in FIGS. 9B to 9D.

That is, the electrodes 19a connected to the wires 19c may be thinned out, as shown in FIG. 9B. Also, the electrodes 19b may be connected at one ends to the electrode 19a, as shown in FIG. 9C. Moreover, the electrodes 19a connected to the wires 19c in the configuration of FIG. 9C may be thinned out, as shown in FIG. 9D.

In the second embodiment, since the low-reflection metal layer is used as the second electrode pattern 19, the reflection of the second electrode pattern 19 into the display area M is restrained. Also, in order to restrain the reflection into the display area M, a low-reflection metal layer may be used at least for one of the first electrode pattern 6 and the second electrode pattern 19.

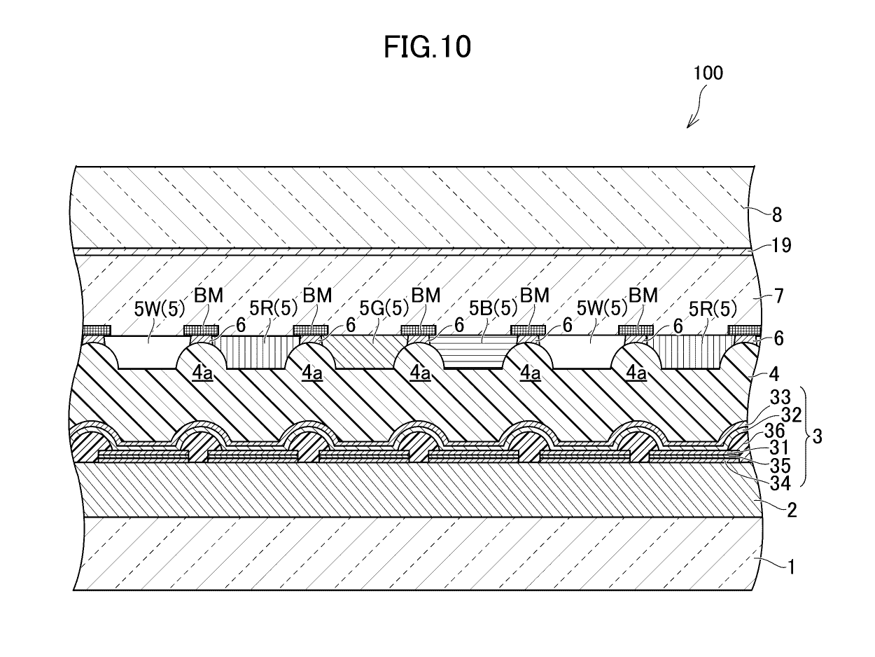

FIG. 10 is a schematic cross-sectional view showing a display device according to a modification of the second embodiment. While the configuration in which the second electrode pattern 19 is formed on the top surface of the counter substrate 8 is described with reference to FIG. 7, the second electrode pattern 19 may be formed on the bottom surface of the counter substrate 8, as shown in FIG. 10. Even with such a configuration where the first electrode pattern 6 and the second electrode pattern 19 for detecting a touch input are provided respectively on both sides of the filling layer 7 as an insulating layer, effects similar to those described in the second embodiment can be achieved.

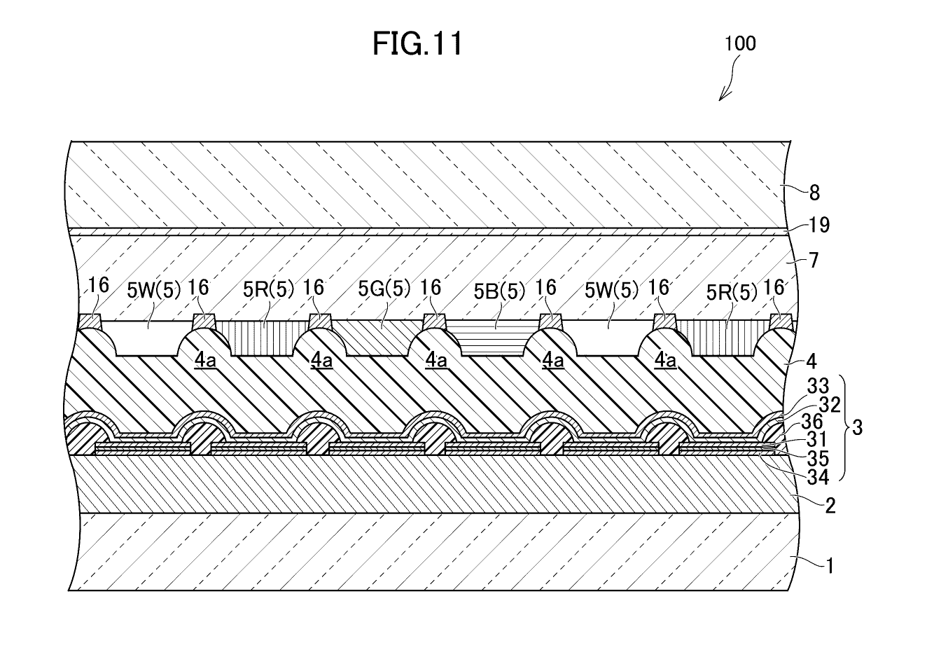

FIG. 11 is a schematic cross-sectional view showing a display device according to a third embodiment. The same configurations as those in the first embodiment are denoted by the same reference signs and will not be described further in detail.

In the first embodiment and the second embodiment, a transparent conductive material is used as the material of the first electrode pattern, whereas in the third embodiment, a low-reflection metal is used as the material of the first electrode pattern. As the low-reflection metal, titanium, tungsten, molybdenum and the like, which are metals having a lower reflectivity for visible range than aluminum, may be used.

In the third embodiment, since the first electrode pattern 16 as the low-reflection metal film functions as a light shielding film as well, there is no need to provide the black matrix BM separately. In the third embodiment, since the black matrix BM is not formed on top of the first electrode pattern 16, the first electrode pattern 16 is formed to be higher by that amount than in the first embodiment and the second embodiment. As shown in FIG. 11, since the partition walls are formed to be higher than the areas filled with the materials of the colored layers, there is no mixture of the materials of the colored layers next to each other at the time of filling the colored layers. The colored layers are separated from each other by the partition walls, thus restraining the optical mixture of colors. Also, with the configuration in the third embodiment, since the black matrix BM is not used, the cost can be restrained by that amount.

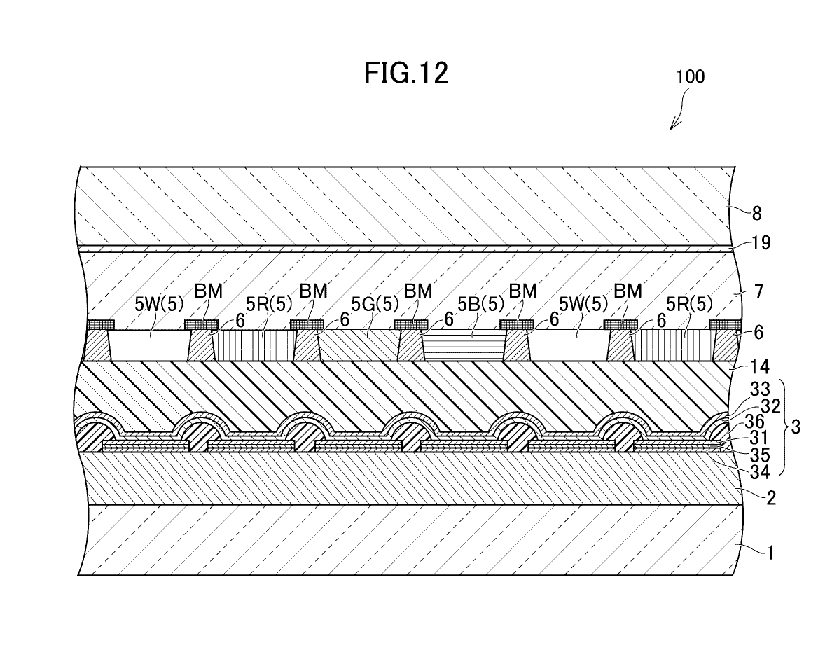

FIG. 12 is a schematic cross-sectional view showing a display device according to a fourth embodiment. The same configurations as those in the first embodiment are denoted by the same reference signs and will not be described further in detail.

In the fourth embodiment, an underlying layer 14 is formed on the light emitting element layer 3, and the first electrode pattern 6 and the color filter layer 5 are formed on the underlying layer 14.

In the fourth embodiment, the top surface of the underlying layer 14 is a flat surface. This is because the underlying layer 14 has a multilayer structure including an organic layer.

Specifically, a SiN (silicon nitride) layer is formed on the upper electrode 33, and the SiN layer has a convex top surface following the shape of the bank layer 36. The organic layer is formed on this SiN layer. The side facing the SiN layer, of the organic layer, has a shape following the convex shape of the SiN layer, whereas the side opposite to the side facing the SiN layer is a flat surface. Also, an SiN layer is further formed on the flat surface of the organic layer. The SiN layer formed on the organic layer with the flat surface has a flat top surface. Here, the flat surface refers to a state where the degree of concavity/convexity of the underlying layer 14 is lower than the degree of concavity/convexity of the upper electrode 33, and it does not have to be a perfectly flat surface.

As described above, in the fourth embodiment, a multilayer structure in which a SiN layer, an organic layer and a SiN layer are stacked in this order is employed as the underlying layer 14. However, the underlying layer 14 is not limited to such a multilayer structure. It suffices that the underlying layer 14 has at least one organic layer and a flat top surface.

The first electrode pattern 6 is formed on the underlying layer 14. In the fourth embodiment, the first electrode pattern 6 forms the entirety of the partition walls from the bottom to the top. The spaces between the partition walls formed by the first electrode pattern 6 are filled with the materials of the colored layers, and the respective colored layers 5W, 5R, 5G, 5B are districted by the partition walls. In the fourth embodiment, since the top surface of the underlying layer 14 is a flat surface, the formation of the first electrode pattern 6 and the patterning of the colored layers 5W, 5R, 5G, 5B are easier than in the other embodiments.

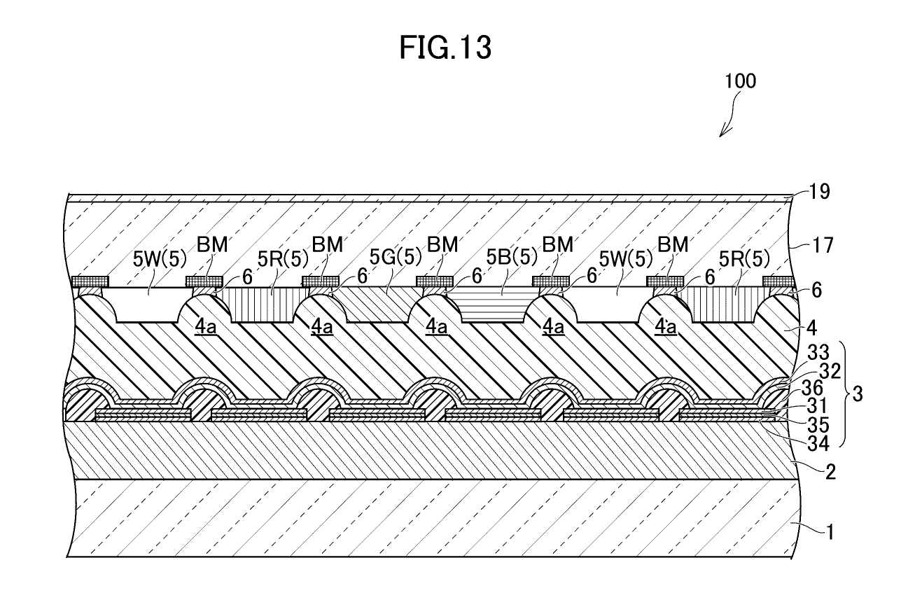

FIG. 13 is a schematic cross-sectional view showing a display device according to a fifth embodiment. The same configurations as those in the first to fourth embodiments are denoted by the same reference signs and will not be described further in detail.

As shown in FIG. 13, the display device 100 according to the fifth embodiment has a transparent cover layer 17 instead of the filling layer 7 described in the first embodiment, and does not have the counter substrate 8. That is, in the fifth embodiment, the first electrode pattern 6 and the second electrode pattern 19 for detecting a touch input are provided respectively on both sides of the cover layer 17 as an insulating layer.

According to the fifth embodiment, since the counter substrate is not provided, the display device 100 can be reduced in thickness by that amount, in addition to the effect that the optical mixture of colors can be restrained by the demarcation of the colored layers from each other by the partition walls as described in the other embodiments.

While the color filter layer 5 having the white colored layer 5W, the red colored layer 5R, the green colored layer 5G and the blue colored layer 5B is used in the description of the first to fifth embodiments, this is not limiting and any color filter layer having colored layers of a plurality of colors may be used. Also, as the method for forming the color filter layer, printing methods other than the inkjet method, such as letterpress printing and flexographic printing, or patterning methods such as photolithography and laser transfer may be used. While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a light emitting element layer which emits light, with luminance controlled in each of a plurality of unit pixels forming an image;
a color filter layer which has colored layers of a plurality of colors, with the colored layer of one color corresponding to one of the unit pixels;
an insulating layer; and
a first electrode and a second electrode provided on both sides of the insulating layer, respectively, in order to detect a touch input;
wherein the colored layers next to each other are districted by a partition wall, and
at least apart of the partition wall in a direction of height is formed by the first electrode.

2. The display device according to claim 1, wherein the insulating layer is made up of only one layer covering the color filter layer and the first electrode.

3. The display device according to claim 1, wherein the insulating layer includes a first layer covering the color filter layer and the first electrode, and a second layer stacked on the first layer.

4. The display device according to claim 1, wherein the partition wall has a height equal to or above a height of the color filter layer.

5. The display device according to claim 1, wherein the colored layers next to each other are separated from each other by the partition wall.

6. The display device according to claim 1, further comprising an underlying layer which includes the color filter layer and the first electrode and covers the light emitting element layer,
wherein the underlying layer has a convex part forming a bottom part of the partition wall, and
the first electrode is formed on the convex part, thus forming a top part of the partition wall.

7. The display device according to claim 1, further comprising an underlying layer which includes the color filter layer and the first electrode and covers the light emitting element layer,
wherein the underlying layer has a flat top surface, and
the first electrode is formed on the flat top surface, thus forming the partition wall.

8. The display device according to claim 1, wherein at least one of the first electrode and the second electrode is made of a transparent conductive material.

9. The display device according to claim 1, wherein at least one of the first electrode and the second electrode is made of a low-reflection metal film.
